(19) United States
(12) Patent Application Publication
(10) Pub. No.: US 2025/0311338 A1
(43) Pub. Date: Oct. 2, 2025

(54) SOURCE & DRAIN BODIES IN STACKED TRANSISTOR ARCHITECTURES

(71) Applicant: Intel Corporation, Santa Clara, CA (US)

(72) Inventors: Zhiyi Chen, Portland, OR (US); Anand Murthy, Portland, OR (US); Marvin Paik, Portland, OR (US); Glenn Glass, Portland, OR (US)

(73) Assignee: Intel Corporation, Santa Clara, CA (US)

(21) Appl. No.: 18/621,807

(22) Filed: Mar. 29, 2024

(51) Int. Cl. H01L 29/08; H01L 29/06; H01L 29/167; H01L 29/417; H01L 29/66; H01L 29/775; H01L 29/786

(52) U.S. Cl. CPC H10D 62/151; H10D 30/014; H10D 30/0321; H10D 30/0323; H10D 30/43; H10D 30/6729; H10D 30/6757; H10D 62/121; H10D 62/834

(57) ABSTRACT

Integrated circuitry comprising a ribbon or wire (RoW) transistor stack structure including a plurality of individual source and/or drain material bodies of a same conductivity type. A metallization interfaces with an individual one of the source and/or drain material bodies, achieving a larger interface area for lower contact resistance. In some examples, a source and/or drain material protrusion is formed at opposite ends of each of a plurality of channel structures. The protrusions may be of a first composition, such as p-type SiGeₓ for a PMOS device. The protrusions may then be augmented into larger bodies through the formation of another layer of material, such as SiGe_{y} for a PMOS device, where y is larger than x. In some further examples, an outer layer of an individual layered source and/or drain body may be enriched with Ga (e.g., SiGe:Ga) to further reduce contact resistance of a transistor stack structure.

### BACKGROUND

Demand for higher performance integrated circuits (ICs) in electronic device applications has motivated increasingly dense transistor architectures. Stacked gate-all-around (GAA) transistor structures, such as ribbon or wire (RoW) structures, include a plurality of channel material structures that are in a vertical stack with one channel structure over another.

For any transistor architecture, it is advantageous to reduce extrinsic electrical resistances. Extrinsic resistance may be limited by a conductivity of source and/or drain semiconductor material and/or a contact resistance between the source and/or drain semiconductor material and a contact metallization. For stacked transistor structures, the device geometry and/or small spaces between vertically stacked channel regions may induce higher extrinsic resistance.

Fabrication techniques and stacked transistor architectures that reduce extrinsic resistance for even the most aggressively scaled devices are therefore commercially advantageous.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 illustrates an isometric sectional view of a transistor stack structure including a stack of multiple source or drain bodies, in accordance with some embodiments;

FIG. 2 is a flow diagram illustrating methods of forming a transistor structure including a stack of multiple source or drain bodies, in accordance with some embodiments;

FIG. 3 is a flow diagram illustrating methods of forming a stack of Ga-enriched layered SiGe source and drain bodies, in accordance with some stacked PMOS transistor embodiments;

FIG. 4A illustrates a first cross-sectional isometric view of a pair of stacked channel structures, in accordance with some embodiments;

FIG. 4B illustrates a second cross-sectional isometric view of one of the stacked channel structures shown in FIG. 4A, in accordance with some embodiments;

FIG. 5A illustrates a first cross-sectional isometric view of a pair of stacked channel structures after forming individual source and drain material protrusions, in accordance with some embodiments;

FIG. 5B illustrates a second cross-sectional isometric view of one of the stacked channel structures shown in FIG. 5A, in accordance with some embodiments;

FIG. 6A illustrates a first cross-sectional isometric view of a pair of stacked channel structures after filling in a trench between the stacked channel structures, in accordance with some embodiments;

FIG. 6B illustrates a second cross-sectional isometric view of one of the stacked channel structures shown in FIG. 6A, in accordance with some embodiments;

FIG. 7A illustrates a first cross-sectional isometric view of a pair of stacked channel structures after opening the trench between the stacked channel structures and augmenting the individual source and drain material protrusions with another layer of source and drain material, in accordance with some embodiments;

FIG. 7B illustrates a second cross-sectional isometric view of one of the stacked channel structures shown in FIG. 7A, in accordance with some embodiments;

FIG. 8A illustrates a first cross-sectional isometric view of a pair of stacked channel structures after depositing a conductive material in direct contact with an individual source and drain material protrusion, in accordance with some embodiments;

FIG. 8B illustrates a second cross-sectional isometric view of one of the stacked channel structures shown in FIG. 8A, in accordance with some embodiments;

FIG. 9 illustrates a mobile computing platform and a data server machine employing an IC including a transistor stack structure with reduced external resistance, in accordance with embodiments; and

FIG. 10 is a functional block diagram of an electronic computing device, in accordance with some embodiments.

### DETAILED DESCRIPTION

Embodiments are described with reference to the enclosed figures. While specific configurations and arrangements are depicted and discussed in detail, this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. These terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause-and-effect relationship).

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

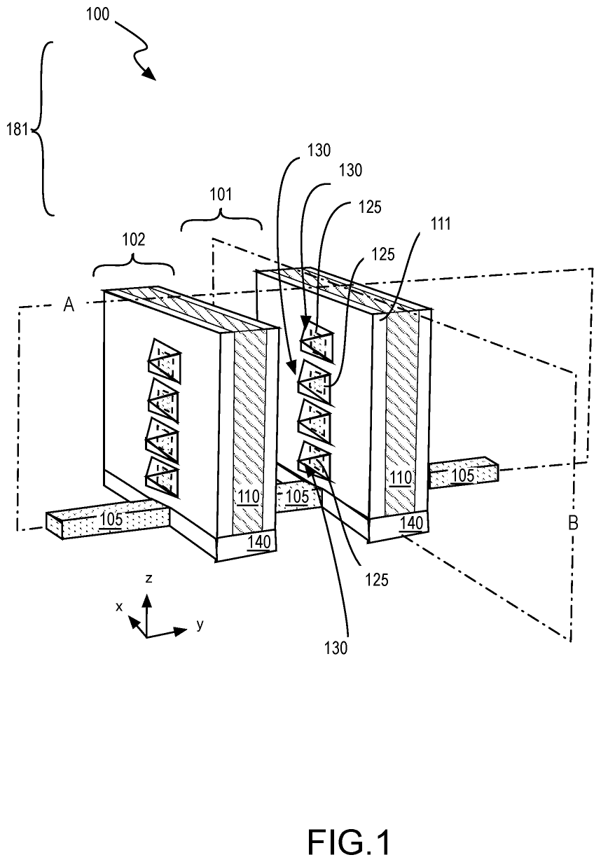

The inventors have determined extrinsic resistance of a stacked transistor structure can be reduced if contact metallization is interfaced to multiple, individual source/drain material bodies rather than interfacing with a single contiguous source/drain material. FIG. 1 illustrates an isometric sectional view of an integrated circuit (IC) portion 100, which includes two adjacent transistor stack structures 101 and 102. Each of transistor stack structures 101, 102 include a stack of multiple source and/or drain bodies 130. Transistor stack structures 101, 102 have a GAA transistor architecture with a plurality of stacked channel regions, layers, or structures 125 surrounded by a gate electrode material 110. Transistor stack structures 101, 102 are illustrated as including a vertical (e.g., z-axis) stack of four active channel structures, but transistor stack structures 101, 102 may include any integer number of channel regions (e.g., 2, 3, 4, 5 . . . 10 . . . 20, etc.) as embodiments herein are not limited in this respect. Channel structures 125 may each have any dimensions and architecture, such as a ribbon or wire (RoW) of any thickness (e.g., z-dimension), width (e.g., x-dimension), and length (e.g., y-dimension), etc.

Channel structures 125 are over a sub-channel material 105, which may have been part of a workpiece substrate, such as a large format semiconductor wafer, for example. An integrated circuit including IC portion 100 may include any number of backend interconnect metallization levels 181 over a “top” or “front” side of transistor structures 101 and 102. Metallization levels 181 may have any known structure interconnecting one or more transistor terminals with other nodes in a circuit topology. Structural aspects of sub-channel material 105 and metallization levels 181 are not depicted in FIG. 1 to avoid obscuring the view of transistor stack structures 101, 102. However, it is in reference to sub-channel material 105 and/or metallization levels 181 that channel structures 125 may be referred to herein as within a vertical stack between overlying metallization levels 181 and underlying substrate material 105.

In FIG. 1, two orthogonal planes A and B are demarked by dashed line. Plane A is a “gate-cut” plane that passes through a transverse width of a gate electrode 110 and passes through a longitudinal length of channel structures 125. Plane B is a “fin-cut” plane that passes through a transverse width of the stacks of channel structures 125 and passes through a longitudinal length of one gate electrode 110.

Transistor stack structures 101, 102 may each comprise one or more transistors within each stack structure. For embodiments where stack structure 101 (and 102) includes a plurality of transistors, the two or more transistors may each include one or more of channel structures 125. The four channel structures 125 illustrated may therefore be components of a single transistor, or each a component of a different transistor. If there are multiple transistors within each of stack structure 101 and/or 102, they may be of the same conductivity type (e.g., PMOS), or of complementary conductivity types (e.g., a CMOS stacked transistor, or “CFET”).

In accordance with some embodiments, transistor stack structures 101 and 102 include a PMOS stack where at least two of channel structures 125 are coupled at opposite ends to source and/or drain bodies 130 having p-type conductivity. In some exemplary embodiments, all of channel structures 125 are portions of one or more p-type transistors. In one illustrative embodiment, all of channel regions 125 are operable to contribute to a total drive current of a single (e.g., PMOS) transistor.

As described further below, a plurality of source and/or drain bodies 130 are in a vertical stack, with each individual source/drain body 130 being a head, or “nub,” at an end of one channel structure 125. This stack of individual source/drain bodies 130 is in contrast to a single contiguous body that unifies the stack of channel structures 125. Individual source and/or drain bodies 130 are ready to be directly contacted with a metallization (e.g., source/drain contact metallization), which is not depicted in FIG. 1 to avoid obscuring the stack of source and/or drain bodies 130. The surface area of each individual source and/or drain body 130 may be entirely covered by the contact metallization, reducing contact resistance for any given specific contact resistivity. Contact metallization may extend along, or line a sidewall of, the entire vertical height of each transistor stack structure 101, 102 effectively providing a localized vertical interconnect route across the stack of source and/or drain bodies 130. Any vertical spacing between adjacent source and/or drain bodies 130 may be spanned by the contact metallization. According to embodiments herein, a total volume of the source and/or drain bodies 130 may be reduced in favor of metallization.

Source and/or drain bodies 130 are electrically and physically coupled to opposite sides of channel structures 125. In this example, source and/or drain bodies 130 are each faceted epitaxial material that has been grown, for example laterally from an end seeding surface of channel structures 125 which are otherwise embedded in one or more dielectric materials 111. However, source and drain bodies 130 need not be epitaxial material, in which case the facets shown in FIG. 1 may not be present.

In some PMOS embodiments, each source/drain body 130 comprises a SiₓGe_{y} alloy with one or more p-type (acceptor) impurities. As further described below, each source/drain body 130 may include multiple layers with different alloy compositions and/or impurity dopant compositions. Although described below in the context of a PMOS transistor stack structure, transistor stack structures 101, 102 may be similarly implemented as an NMOS transistors stack. For such embodiments, the principles taught in the context of a PMOS transistor stack structure may be likewise applied toward reducing extrinsic electrical resistance of an NMOS transistor stack structure.

Gate electrode 110 is between channel structures 125, and between dielectric material 111. A gate insulator (not depicted) is between gate electrode 110 and each channel structure 125. Transistor stack structures 101, 102 may further include one or more additional dielectric materials. In the illustrated example, an isolation dielectric material 140 is under gate electrode 110 where gate electrode 110 extends laterally beyond a sidewall of channel structures 125. Other dielectric material (not depicted) may surround source and/or drain bodies 130, as well as gate electrode 110.

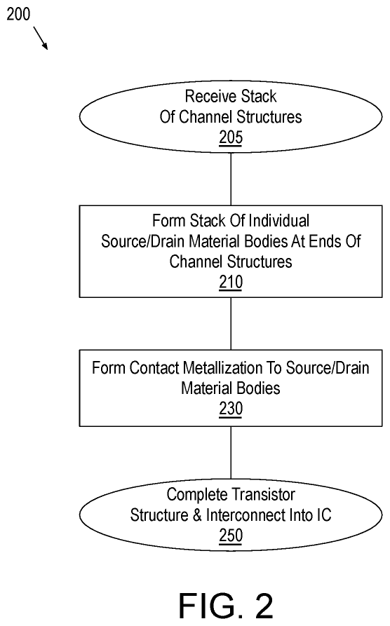

FIG. 2 is a flow diagram illustrating methods 200 for forming a transistor stack structure including a stack of multiple source or drain bodies, in accordance with some embodiments. Methods 200 begin at input 205 where a workpiece, such as a 300 mm semiconductor material wafer, is received. The workpiece includes a stack of channel structures as fabricated according to any suitable techniques upstream of methods 200. At block 210 a stack of individual source and/or drain material bodies are formed at exposed ends of the channel structures, resulting in a stack of two or more discrete source/drain material bodies. In exemplary embodiments, block 210 entails an epitaxial growth process that may seed from exposed end surfaces of crystalline material of the channel structures. In some PMOS embodiments where the channel material is substantially single crystalline silicon, a substantially single-crystal SiGe alloy is grown at block 210. The SiGe alloy comprises one or more acceptor impurities. In advantageous embodiments, the composition of the SiGe alloy is modulated over a duration of the growth and/or between multiple growth cycles, for example to form compositionally layered or graded source and/or drain material bodies. The growth process is performed for a sufficient total duration that a thickness of the source and/or drain material bodies becomes larger than a corresponding thickness of the channel material, but ideally not so long that a first source or drain material body seeded from a first channel structure merges with a second source or drain material body seeded from a second channel structure immediately above or below the first channel structure.

Methods 200 continue at block 230 where a contact metallization is deposited to contact the individual source or drain material bodies. The contact metallization advantageously contacts the enlarged surface of each source or drain material body increasing the contact surface area between the metallization. For embodiments where each source or drain body is compositionally layered or graded, the enlarged metallization interface area contact resistance may be further reduced.

Methods 200 end at output 250 where a transistor structure is completed according to any known techniques and terminals of the transistor structure are interconnected into integrated circuitry through the fabrication of any number of metallization features (e.g., lines and vias) within any number of interconnect metallization levels.

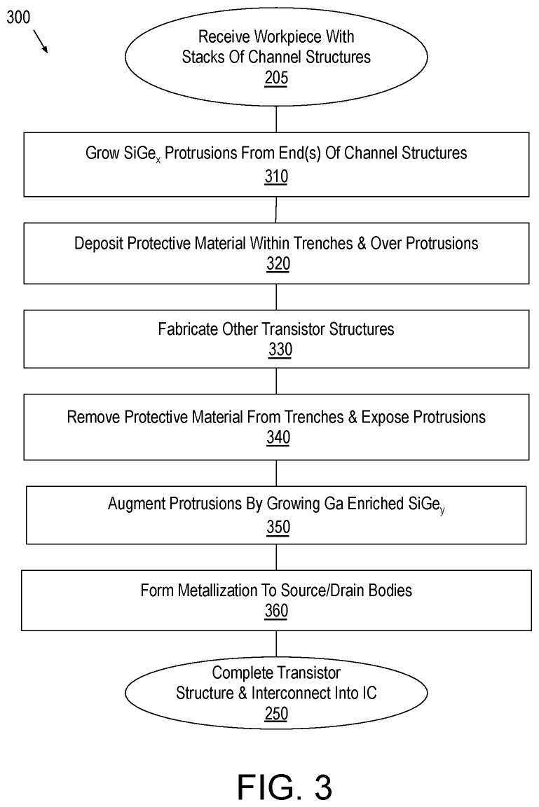

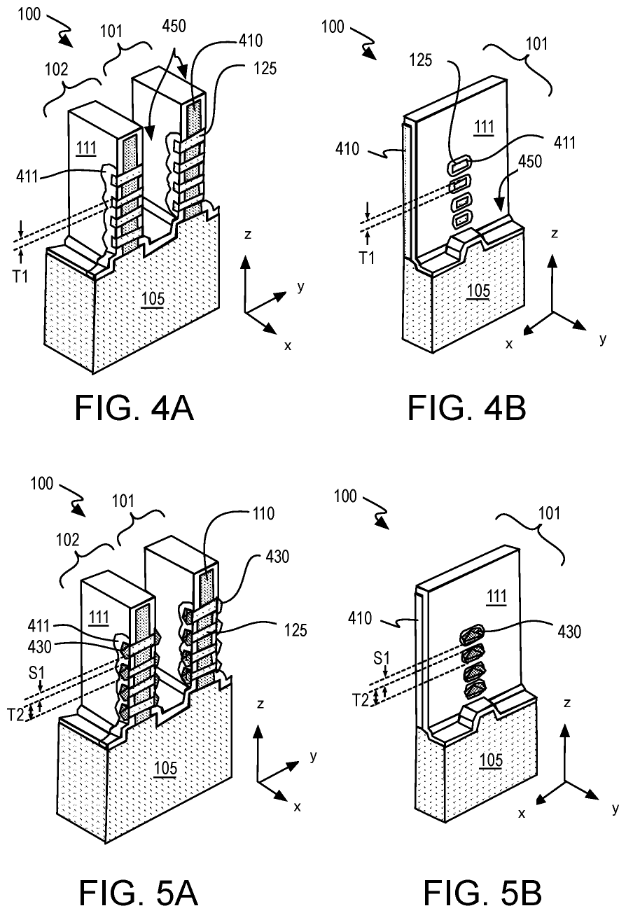

FIG. 3 is a flow diagram illustrating methods 300 for forming a stack of Ga-enriched layered SiGe source and drain bodies, in accordance with some stacked PMOS transistor embodiments. Methods 300 again begin at input 205 with receipt of a workpiece suitable for IC fabrication. A working surface of the workpiece comprises a plurality of channel structure stacks, for example that are to be further processed into transistor stack structures. FIG. 4A illustrates a cross-sectional view of channel stack structures corresponding to the transistor stack structure 101 and transistor stack structure 102 along the A-A′ plane introduced in FIG. 1, in accordance with some embodiments. FIG. 4B illustrates a second cross-sectional view a channel stack structure corresponding to transistor stack structure 101 along the B-B′ plane introduced in FIG. 1.

As shown in FIG. 4A, adjacent channel stack structures are separated by an intervening space or trench 450. Channel structures 125 have a longitudinal channel length (e.g., along y-axis) extending between two trenches 450. Channel structures 125 extend through dielectric material 111, and one or more additional dielectric materials 411 may be adjacent to an end surface of channel structures 125 exposed along a sidewall of trench 450. Channel structures 125 are bodies of semiconductor material that may have been patterned from a fin of a substrate material layers, for example. Although the substantially rectilinear profiles of channel structures 125 illustrated in FIGS. 4A and 4B are simplifications, an exposed end surface of each channel structure 125 has a thickness T1 regardless of the channel structure profile. Thickness T1 may be associated with a layer thickness of an epitaxial stack, for example. Although channel structures 125 are illustrated in FIG. 4B as nanoribbons having a transverse width greater than thickness T1, channel structures 125 may instead have alternative forms. For example, channel structures 125 may also be nanowires of nearly equal thickness and width.

In exemplary embodiments, channel structures 125 are crystalline semiconductor. Although the crystalline semiconductor includes polycrystalline thin film material, the crystalline semiconductor may be advantageously substantially monocrystalline. In some such embodiments, the crystallinity of channel structures 125 is cubic with the top surfaces (opposite substrate material 105) having crystallographic orientation of (100), (111), or (110), for example. Other crystallographic orientations are also possible. In some embodiments, channel structures 125 are a substantially monocrystalline group IV semiconductor material, such as, but not limited to substantially pure silicon (e.g., having only trace impurities), silicon alloys (e.g., SiGe), or substantially pure germanium (e.g., having only trace impurities). Channel structures 125 may also have any of these same exemplary compositions in alternative polycrystalline or amorphous embodiments, for example where a channel structure stack has been fabricated from thin film semiconductor material layers. Although in exemplary embodiments channel structures 125 each have a substantially homogenous composition, a channel structure 125 may alternatively comprise one or more semiconductor heterojunctions that, for example further include a first semiconductor material adjacent to a second semiconductor material.

As further illustrated in FIGS. 4A and 4B, channel structures 125 are separated from each other by an intervening material 410, which may be subsequently replaced with a gate stack (e.g., comprising a gate insulator and gate electrode material). Intervening material 410 may have any compatible composition, such as SiGe for embodiments where channel structures 125 are substantially single crystalline silicon.

Returning to FIG. 3, methods 300 continue at block 310 where semiconductor material is grown from individual exposed ends of the channel structures. The growth is advantageously selective to the channel structure surfaces, and may comprise a vapor phase epitaxy/deposition process, for example a low pressure CVD (LPCVD) process performed a temperature in the range of 325-500° C. and a pressure in the range of 5-20 Torr. Precursor gases may be co-flowed or cyclically flowed, for example in a dep-etch process. Precursor gases may include silane, silicon tetrachloride, germanium tetrachloride, or the like. The material grown at block 310 may comprise one or more electrically active impurities that are cither introduced in-situ during epitaxial growth, or implanted into the semiconductor material subsequent to material growth. According to some exemplary embodiments, the volume of semiconductor material grown at block 310 is limited to form a plurality of separate crystals that can each serve as a seed for subsequent additional material growth.

In the example illustrated in FIGS. 5A and 5B, semiconductor material protrusions 430 have been selectively formed upon the end faces of channel structures 125. In exemplary PMOS embodiments, semiconductor material protrusions 430 are p-type, comprising at least one of a p-type (acceptor) impurity species, such as boron. Although acceptor concentrations may vary with species and implementation, in exemplary boron embodiments semiconductor material protrusions 430 have a boron concentration less than 2e21 atoms/cm³. In some specific examples, boron concentration is in the range of 4-5e20 atoms/cm³.

For embodiments where the channel structures 125 are substantially pure silicon, semiconductor material protrusions 430 are also a Group IV material, such as silicon, germanium, or a silicon-germanium alloy having a first germanium concentration (SiGeₓ). In some exemplary PMOS embodiments, protrusions 430 are SiGeₓ having a germanium concentration less than 50 atomic percent (at. %). Although germanium concentration may vary with implementation, in some examples the germanium concentration is at least 20 at. % and may be in the range of 20-40 at. %.

As further illustrated in FIG. 5A and FIG. 5B, source and drain semiconductor material protrusions 430 are grown to have a thickness T2, greater than the corresponding thickness T1 of channel structures 125. Thickness T2 is limited such that adjacent protrusions remain spaced apart by an intervening non-zero gap or space S1. Source and drain semiconductor material protrusions 430 therefore remain a stack of individual bodies.

Returning to FIG. 3, methods 300 continue at block 330 where a protective material is deposited over the source and drain semiconductor material protrusions formed at block 320. The deposited material may protect source and drain semiconductor material from subsequent fabrication operations. Advantageously, the material deposited at block 330 may limit the loss of impurity dopants from within the underlying source and drain semiconductor material bodies during subsequent fabrication operations. The material deposited at block 320 may have any chemical composition suitable as a protective layer and that can be subsequently removed with adequate selectively relative to other materials present within the stacked transistor structure. In some embodiments, a silicon-based dielectric material or a carbon-based dielectric material is deposited at block 320, for example with a chemical vapor deposition process or a spin-on/cure process.

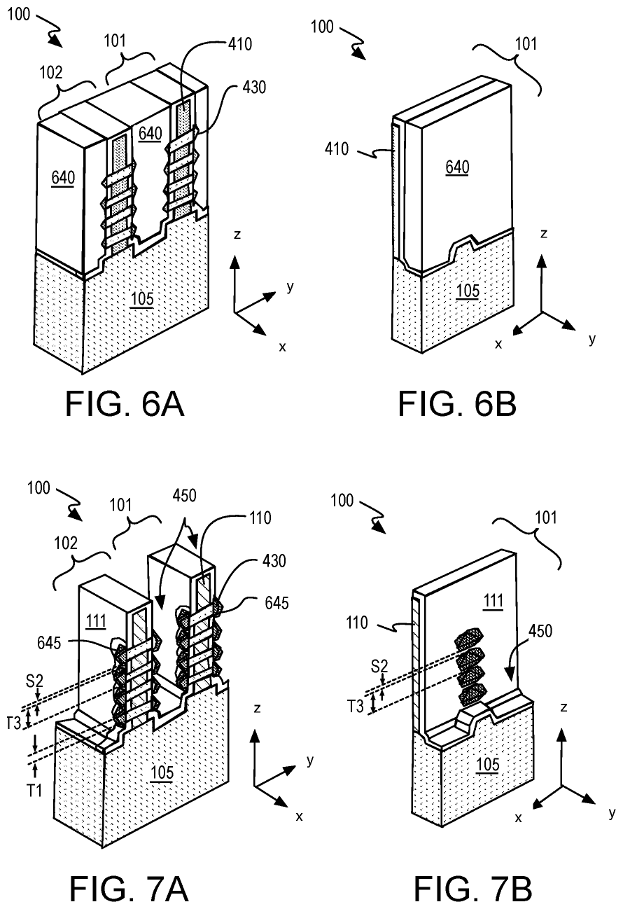

In the example illustrated in FIGS. 6A and 6B, material 640 has been deposited over source and drain semiconductor material protrusions 430. In this example, material 640 substantially fills trench 450 between adjacent channel stack structures. In advantageous embodiments, material 640 retards outdiffusion of impurity dopants (e.g., boron in exemplary PMOS embodiments) from source and drain semiconductor material protrusions 430, which may otherwise occur during subsequent fabrication operations, particularly those involving elevated temperatures (e.g., exceeding 400° C.).

Returning to FIG. 3, methods 300 continue at block 330 where one or more fabrication operations are performed. Such operations may entail any frontside or backside processing of a workpiece comprising stacked transistor structures. Frontside processing may comprise a thermal annealing of transistor structures formed thus far. For example, the source and drain material protrusions may be annealed and impurities (e.g., that had been implanted) within the source and drain material electrically activated, and/or impurities present within the source and drain material may be thermally driven into ends of the channel structures. Frontside processing may also (or in the alternative) entail the further formation of one or more additional transistor structures. In some embodiments, at block 330 sacrificial material between channel material structures is replaced with a gate stack comprising a gate insulator and a gate electrode. For example, while source and drain material protrusions are protected, a wet chemical etch process is utilized to remove sacrificial layers (e.g., comprising SiGe) selectively from intervening channel structures (e.g., comprising Si) to expose the channel structures as ribbons or wires. Following the exposure of channel structures, gate insulator material and gate electrode material may be deposited (e.g., by atomic layer deposition) around the channel structures while source and drain material protrusions remain protected. After the gate structure is formed, the transistor stack structures may be heated to a temperature of over 400° C. (e.g., 500° C., 750° C., or 850° C.) for a predetermined time in the presence of any suitable ambient, such as, but not limited to, nitrogen (N₂), or forming gas (N₂:H₂). Such a post-gate thermal cycle may be performed to set a transistors threshold voltage (Vi), for example.

Following operations performed at block 330, methods 300 continue at block 340 where at least a portion of the material deposited at block 320 is removed to expose the source and drain material protrusions formed at block 310. Any etch process selective to the composition of the material deposited at block 320 may be practiced at block 340 as embodiments are not limited in this respect.

Methods 300 continue at block 350 where the source and drain material protrusions formed at block 310 are augmented with a further deposition of semiconductor material. Material growth is advantageously selective to the to the source and drain material protrusions relative to one or more dielectric materials surrounding the protrusions. In some embodiments, a vapor phase epitaxy or deposition process is performed at block 350. The process may be similar to that performed at block 310 (e.g., performed a temperature in the range of 325-500° C. and a pressure in the range of 5-20 Torr). Precursor gases may again be introduced either cyclically or co-flowed and may similarly include silane, silicon tetrachloride, germanium tetrachloride, or the like. In some PMOS embodiments where a silicon-germanium alloy was grown at block 310, a silicon-germanium alloy is also grown at block 350. However, in exemplary embodiments, the silicon-germanium alloy grown at block 350 has a significantly higher germanium concentration than that grown at block 310. For example, the atomic percentage of germanium in the material grown at block 350 may be two, or even three, times that of the material grown at block 310. Higher germanium concentrations have been found to reduce external resistance, and although not bound by theory, it is thought to lower the barrier height between the semiconductor material grown at block 350 and subsequently deposited contact metallization.

The semiconductor material grown at block 350 may comprise one or more electrically active impurities that are either introduced in-situ during epitaxial growth, or implanted into the semiconductor material subsequent to material growth. In exemplary PMOS embodiments, p-type semiconductor material comprising at least one acceptor impurity species, such as boron, is grown at block 350. In advantageous embodiments, a greater concentration of p-type dopants are introduced at block 350 than at block 310. Higher acceptor concentrations can also reduce external resistance by lowering the barrier height between the semiconductor material grown at block 350 and subsequently deposited contact metallization. In further embodiments, p-type semiconductor material comprising multiple acceptor impurity species, such as both boron and gallium, is grown at block 350. Although not bound by theory, gallium enrichment of SiGe_{y} material may lower bandgap of the semiconductor material and/or improve band alignment with subsequently deposited contact metallization.

In the example illustrated in FIGS. 7A and 7B, material 640 has been removed from within trench 450 between two adjacent channel stack structures. Source and drain material protrusions 430 are augmented with an additional layer of source and drain semiconductor material 645. An as-grown layer thickness of source and drain semiconductor material 645 may vary, for example from 2-8 nm. The resulting layered source and drain material bodies have a total thickness T3, which is greater than thickness T2, and significantly greater than channel structure thickness T1, as introduced above. Although thickness T3 may vary with implementation, in exemplary embodiments, thickness T3 is at least 30% larger than channel structure thickness T1 and may be 50% larger, or more. Although source and drain material 645 may unify individual source and drain material protrusions 430 into a single body, in the illustrated embodiment individual source and drain material bodies remain vertically separated by an intervening non-zero space S2.

Although the composition of source and drain semiconductor material 645 may vary with implementation, in some PMOS embodiments source and drain semiconductor material 645 is a silicon-germanium alloy (SiGe_{y}) comprising over 50 at. % germanium. In some embodiments where source and drain material protrusions 430 comprise 20-40 at. % germanium, source and drain material 645 comprises 60-80 at. % germanium.

Acceptor concentrations within source and drain semiconductor material 645 may similarly vary, for example according to the dopant species and implementation. In some PMOS embodiments where source and drain material protrusions 430 have a boron concentration below 4-5e20 atoms/cm³ range, source and drain semiconductor material 645 has a boron concentration in the range of 2-4e21 atoms/cm³, or more. In some further embodiments, source and drain semiconductor material 645 also comprises gallium, for example as a co-dopant countering any loss of boron solubility that may occur with higher concentrations of germanium. Although the amount gallium enrichment may vary, in some exemplary embodiments where gallium is substantially absent from source and drain material protrusions 430 the concentration of gallium within source and drain semiconductor material 645 is in the range of 1-8e19 atoms/cm³.

Although the layered source and drain semiconductor bodies in accordance with embodiments herein may undergo some amount of atomic diffusion, higher concentrations of p-type impurities within the outer layer of source and drain semiconductor material 645 may be distinguished from lower concentrations within source and drain material protrusions 430 with one or more analysis techniques, such as atom probe tomography (APT), or STEM-EELS (electron energy-loss spectroscopy)/EDS (energy dispersive x-ray spectroscopy).

At the stage of transistor fabrication illustrated in FIG. 7A and FIG. 7B, sacrificial channel stack material 410 has been replaced with gate electrode material 110. Where gate electrode material 110 (and underlying gate insulator) was formed prior to formation of source and drain semiconductor material 645, source and drain semiconductor material 645 may retain a highest concentration of impurities in preparation for interfacing with metallization.

Gate electrode material 110 is separated from channel structures 125 by a gate insulator (not depicted) cladding channel structures 125, for example to provide gate-all-around control of channel conductivity. In the illustrated embodiment, the gate electrode material 110 is a single homogeneous material. For such embodiments, the single homogenous material is a single workfunction metal. In some PMOS embodiments, gate electrode material 110 includes a p-type workfunction metal, which may have a workfunction between about 4.9 eV and about 5.2 eV, for example. Suitable p-type materials include, but are not limited to, ruthenium, palladium, platinum, cobalt, nickel titanium, tungsten, conductive metal nitrides (e.g., TiN, WN), and conductive metal oxides (e.g., ruthenium oxide). Although not illustrated in FIG. 7A, or 7B, a compositionally distinct gate fill metal may be over the workfunction metal where a thickness of the workfunction metal is insufficient to occupy the topography allocated to gate structure. For a CFET transistor stack structures, gate electrode material 110 may include both a p-type workfunction metal and an n-type workfunction metal as embodiments are not limited in this respect.

Gate insulator between gate electrode material 110 and channel structures 125 may vary with implementation. In accordance with some exemplary embodiments, a high-k material (with a bulk relative permittivity greater than 9) is between gate electrode material 110 and channel structures 125. One exemplary high-k material is metal oxide (MIOx). Examples include a metal oxide comprising predominantly aluminum (e.g., AlOx), a metal oxide comprising predominantly magnesium (e.g., MgO), a metal oxide comprising predominantly lanthanum (e.g., LaOₓ), a metal oxide comprising predominantly hafnium (e.g., HfOₓ) or predominantly zirconium (e.g., ZrOₓ). In other examples, the high-k material is an alloy metal oxide comprising significant portions of two or more metals (e.g., HfAlOₓ, or HfZrOₓ).

Returning to FIG. 3, methods 300 continue at block 360 where metallization is deposited directly upon the source and drain material bodies as source and drain (contact) terminal metallization. The metallization deposited at block 360 advantageously spans the stack of source and drain material bodies, filling in any spaces between the bodies and forming a larger semiconductor-metal interface area than would otherwise be possible if the source and drain material bodies had been unified into a single body. Metallization may be deposited at block 360 immediately following the source drain material growth at block 350, ensuring minimal loss of impurity dopants. Metallization may comprise one or more layers of a substantially pure (elemental) metal, or an alloy of one or more metals. In some embodiments, metallization comprising titanium (Ti) is deposited at block 350. In some further embodiments, one or more layers of a metal other than Ti, such as, but not limited to tungsten (W), molybdenum (Mo), niobium (Nb), tantalum (Ta), and/or rhenium (Re) is deposited as a first layer followed by one or more additional layers of metallization (e.g., Ti, nickel, aluminum, copper, cobalt, etc.).

In some embodiments, block 360 comprises a formation of metal silicide through a solid-state reaction at the interface of metallization deposited at block 360 and the semiconductor material deposited at block 350. Silicidation may be promoted with a thermal anneal performed at elevated temperatures subsequent to the deposition of metal.

Following block 360, methods 300 end at output 250 where a stacked transistor structure may be completed according to any known techniques and architectures. The transistor structures may be further interconnected into an IC through any known backend of line (BEOL) interconnect fabrication processes as embodiments are not limited in this respect.

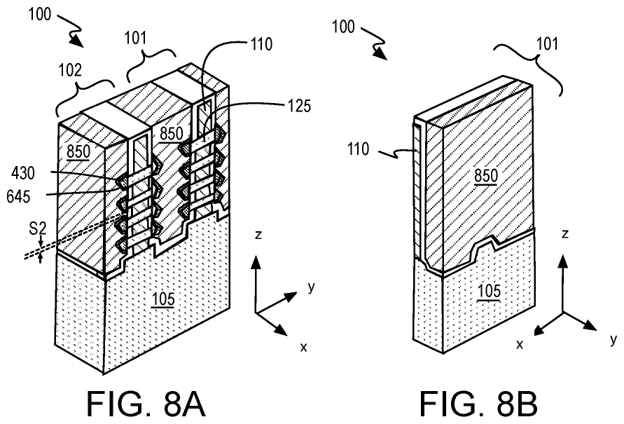

In the example illustrated in FIG. 8A and FIG. 8B, transistor structures 101 and 102 are illustrated as substantially complete three terminal devices comprising source and drain metallization 850. In the illustrated example, metallization 850 substantially fills trench 450 and is in contact with each source and drain material body stacked adjacent to the stack of channel structures 125. Metallization 850 therefore forms a vertical interconnect between individual ones of the plurality of source drain material bodies, and more specifically contacts source and drain semiconductor material 645. Although not depicted, metallization 850 may comprise a liner of a first metal or first metal alloy, which makes direct contact with each of the plurality of source drain material bodies. Over the liner, a fill metal may at least partially fill any remaining gap or trench between adjacent transistor stack structures 101, 102.

In some embodiments, metallization 850 in contact with source and drain semiconductor material 645 is primarily Ti and may be substantially pure Ti. In some further embodiments, a layer of metallization 850 in direct contact with source and drain semiconductor material 645 is other than Ti, such as predominantly W, Mo, Nb, Ta, or Re. For exemplary embodiments where source and drain semiconductor material 645 has a layer thickness of at least 2 nm and comprises Ga, the Ga concentration is at least 1e19 atoms/cm³ within 1-3 nm of the interface with metallization 850. In further embodiments where no Ga was deliberately introduced into source and drain semiconductor material protrusions 430, the concentration of Ga beyond 4 nm of the interface with the metallization 850 is less than 1e18 atoms/cm³.

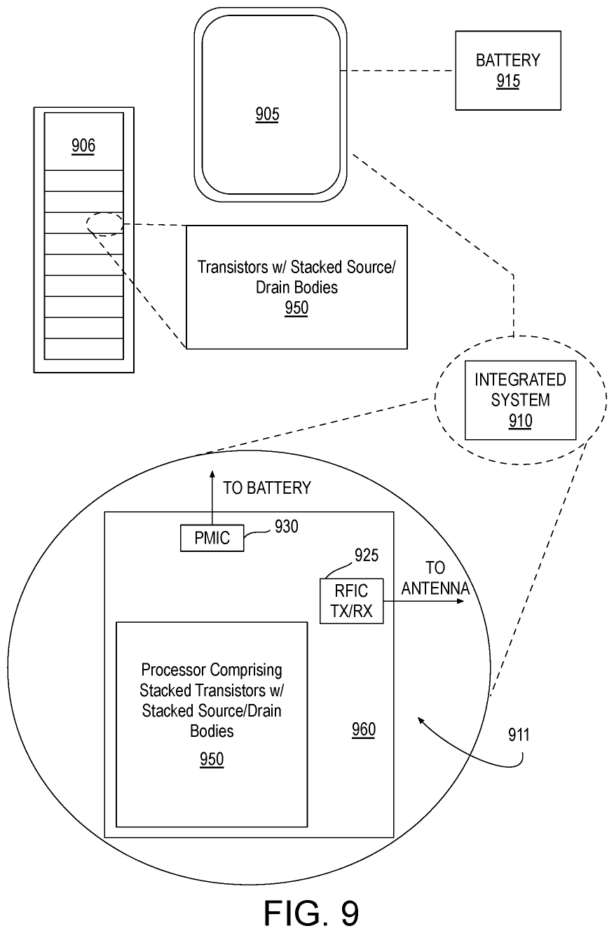

The transistor stack structures 101, 102, and methods of forming such structures described herein, may be integrated into a wide variety of ICs and computing systems that include such ICs. FIG. 9 illustrates a system in which a mobile computing platform 905 and/or a data server machine 906 includes an IC die 950 having a memory and/or microprocessor IC with transistors comprising stacked source and/or drain material bodies, for example in accordance with some embodiments described elsewhere herein. The server machine 906 may be any commercial server, for example including any number of high-performance computing platforms within a rack and networked together for electronic data processing. The mobile computing platform 905 may be any portable device configured for each of electronic data display, electronic data processing, wireless electronic data transmission, or the like. For example, the mobile computing platform 905 may be any of a tablet, a smart phone, laptop computer, etc., and may include a display screen (e.g., a capacitive, inductive, resistive, or optical touchscreen), a chip-level integrated system 910, and a battery 915.

Whether disposed within the integrated system 910 illustrated in the expanded view 911, or as a stand-alone packaged chip within the server machine 906, IC die 950 may include memory circuitry (e.g., RAM), and/or a logic circuitry (e.g., a microprocessor, a multi-core microprocessor, graphics processor, or the like). At least one of these circuitries comprises one or more transistor structures including a stack of source/drain material bodies, for example in accordance with some embodiments described elsewhere herein. IC die 950 may be further coupled to a board or package substrate 960 that further hosts one or more additional ICs, such as power management IC 930 and radio frequency IC 925. RFIC 925 may have an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond.

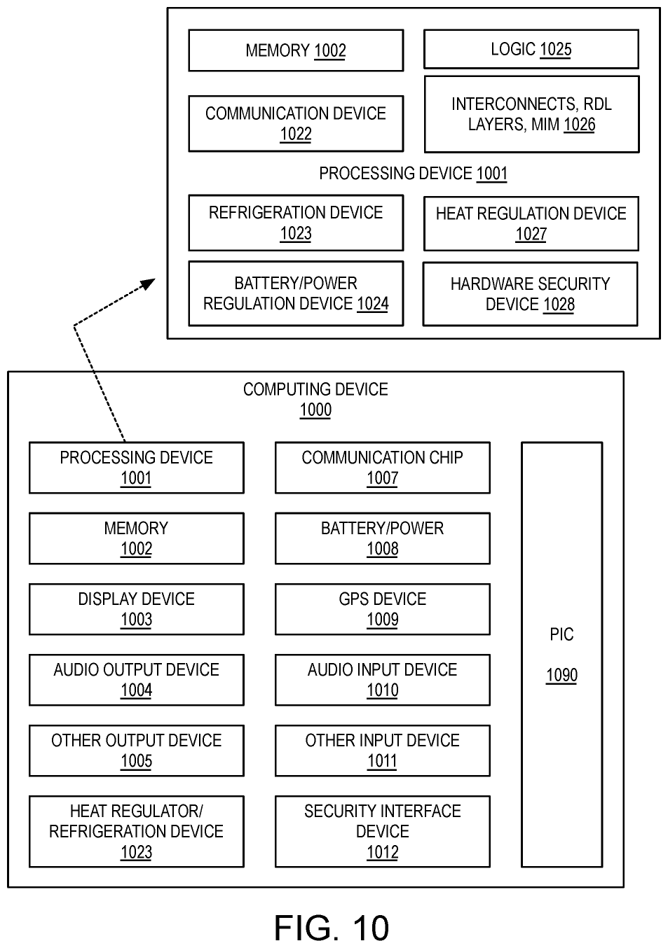

FIG. 10 is a block diagram of a computing device 1000 in accordance with some embodiments. For example, one or more components of computing device 1000 may include any of the transistor structures discussed elsewhere herein. A number of components are illustrated in FIG. 10, but any one or more of these components may be omitted or duplicated, as suitable for the application. In some embodiments, some of the components included in computing device 1000 may be attached to one or more printed circuit boards (e.g., a motherboard). In some embodiments, various ones of these components may be fabricated onto a single system-on-a-chip (SoC) die or implemented with a disintegrated plurality of chiplets or tiles packaged together. Additionally, in various embodiments, computing device 1000 may not include one or more of the components illustrated in FIG. 10, but computing device 1000 may include interface circuitry for coupling to the one or more components. For example, computing device 1000 may not include a display device 1003, but may include display device interface circuitry (e.g., a connector and driver circuitry) to which display device 1003 may be coupled.

Computing device 1000 may include a processing device 1001 (e.g., one or more processing devices). As used herein, the term processing device or processor indicates a device that processes electronic data from registers and/or memory to transform that electronic data into other electronic data that may be stored in registers and/or memory. Processing device 1001 may include a memory 1002, a communication device 1022, a refrigeration/active cooling device 1023, a battery/power regulation device 1024, logic 1025, interconnects 1026, a heat regulation device 1027, and a hardware security device 1028.

Processing device 1001 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable compute units.

Processing device 1001 may include a memory 1002, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, processing device 1001 shares a package with memory 1002. This memory may be used as cache memory and may include embedded dynamic random-access memory (eDRAM) or spin transfer torque magnetic random-access memory (STT-M RAM).

Computing device 1000 may include a heat regulation/refrigeration device 1023. Heat regulation/refrigeration device 1023 may maintain processing device 1001 (and/or other components of computing device 1000) at a predetermined low temperature during operation. This predetermined low temperature may be any temperature discussed elsewhere herein.

In some embodiments, computing device 1000 may include a communication chip 1007 (e.g., one or more communication chips). For example, the communication chip 1007 may be configured for managing wireless communications for the transfer of data to and from computing device 1000. The term “wireless” and its derivatives may be used to describe circuits, devices, systems, methods, techniques, communications channels, etc., that may communicate data through the use of modulated electromagnetic radiation through a nonsolid medium.

Computing device 1000 includes a PIC 1090, for example having a photonic integrated WDM source circuit. PIC 1090 may facilitate communication between one or more instances of processing device 1001 and/or one or more instances of memory 1002, for example.

Computing device 1000 may include battery/power circuitry 1008. Battery/power circuitry 1008 may include one or more energy storage devices (e.g., batteries or capacitors) and/or circuitry for coupling components of computing device 1000 to an energy source separate from computing device 1000 (e.g., AC line power).

Computing device 1000 may include a display device 1003 (or corresponding interface circuitry, as discussed above). Display device 1003 may include any visual indicators, such as a heads-up display, a computer monitor, a projector, a touchscreen display, a liquid crystal display (LCD), a light-emitting diode display, or a flat panel display, for example.

Computing device 1000 may include an audio output device 1004 (or corresponding interface circuitry, as discussed above). Audio output device 1004 may include any device that generates an audible indicator, such as speakers, headsets, or earbuds, for example.

Computing device 1000 may include an audio input device 1010 (or corresponding interface circuitry, as discussed above). Audio input device 1010 may include any device that generates a signal representative of a sound, such as microphones, microphone arrays, or digital instruments (e.g., instruments having a musical instrument digital interface (MIDI) output).

Computing device 1000 may include a global positioning system (GPS) device 1009 (or corresponding interface circuitry, as discussed above). GPS device 1009 may be in communication with a satellite-based system and may receive a location of computing device 1000.

Computing device 1000 may include another output device 1005 (or corresponding interface circuitry, as discussed above). Examples include an audio codec, a video codec, a printer, a wired or wireless transmitter for providing information to other devices, or an additional storage device.

Computing device 1000 may include another input device 1011 (or corresponding interface circuitry, as discussed above). Examples may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 1000 may include a security interface device 1012. Security interface device 1012 may include any device that provides security measures for computing device 1000 such as intrusion detection, biometric validation, security encode or decode, managing access lists, malware detection, or spyware detection.

Computing device 1000, or a subset of its components, may have any appropriate form factor, such as a server or other networked computing component, a mobile device, a printer, a scanner, a monitor, a set-top box, an entertainment control unit, a vehicle control unit, a digital camera, a digital video recorder, or a wearable computing device.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that embodiments described herein may be practiced with modification and alteration without departing from the scope of the appended claims. For example, the above embodiments may include specific combinations of features as further provided below.

In first examples, an apparatus comprises a vertical stack of channel material structures, a gate structure comprising a gate insulator material and a gate electrode material between individual ones of the channel material structures, and a plurality of source or drain material bodies of a same conductivity type. A first of the source or drain material bodies has a first thickness and is in contact with a first of the channel material structures having a second thickness at an end proximal to the first of the source or drain material bodies. The first thickness is larger than the second thickness. The apparatus comprises a metallization structure in contact with the plurality of source or drain material bodies.

In second examples for any of the first examples the first thickness is at least 30% larger than the second thickness.

In third examples, for any of the first through second examples a second of the source or drain material bodies is vertically spaced apart from the first of the channel material structures by a portion of the metallization structure.

In fourth examples for any of the first through third examples a first of the source or drain material bodies comprises silicon and germanium, and a first concentration of germanium proximal to the metallization structure is higher than a second concentration of germanium proximal to a first of the channel material structures.

In fifth examples, for any of the fourth example the first concentration of germanium is over 50 at. %, and the second concentration of germanium is less than 50 at. %.

In sixth examples, for any of the fifth examples the first concentration of germanium is over 60 at. %, and the second concentration of germanium is less than 40 at. %.

In seventh examples, for any of the sixth examples the first concentration of germanium is less than 80 at. %, and the second concentration of germanium is at least 20 at. %.

In eighth examples, for any of the fourth through seventh examples the plurality of source or drain material bodies comprise a first concentration of a p-type impurity proximal to the metallization structure that is higher than a second concentration of the p-type impurity proximal to the channel material structure.

In ninth examples, for any of the eighth examples the p-type impurity is boron and wherein the first concentration is at least 2e21 atoms/cm³; and the second concentration is less than 2e21 atoms/cm³.

In tenth examples, for any of the first through ninth examples an individual one of the source or drain material bodies comprises silicon and germanium and further comprises a concentration of gallium proximal to an interface with the metallization structure.

In eleventh examples, for any of the tenth examples the concentration of gallium is at least 1e19 atoms/cm³ within 1-3 nm of the interface with the metallization structure, and a concentration of gallium beyond 4 nm of the interface with the metallization structure is no more than 1e18 atoms/cm³.

In twelfth examples, for any of the first through eleventh examples the metallization structure comprises a layer of a first metal continuously lining a trench sidewall adjacent to the stack of channel material structures, and the first layer of metal is in contact with a sidewall of each of the plurality of source or drain material bodies, and spans a vertical separate between ones of the plurality of source or drain material bodies.

In thirteenth examples a transistor structure comprises a first material body in a vertical stack with a second material body. The first and second material bodies both comprise silicon. The transistor structure comprises a gate structure within a space between the first and second material bodies, wherein the gate structure comprises a gate electrode material and a gate insulator between the gate electrode material and each of the first and second material bodies. The transistor structure comprises a first source material protrusion and a first drain material protrusion at opposite ends of the first material body. Each of the first source and drain material protrusions comprise silicon and germanium. The transistor structure comprises a second source material protrusion and a second drain material protrusion at opposite ends of the second material body. Each of the second source and drain material protrusions comprise silicon and germanium. The second source and drain material protrusions are vertically spaced apart from the first source and drain material protrusions. The transistor structure comprises a first metallization structure in contact with both of the source material protrusions, and a second metallization structure in contact with both of the drain material protrusions.

In fourteenth examples, for any of the thirteenth examples a portion of the first metallization structure is within a vertical separation between the first and second source material protrusions, and a portion of the second metallization structure is within a vertical separation between the first and second drain material protrusions.

In fifteenth examples, for any of the thirteenth through fourteenth examples a vertical thickness of the first source material protrusion and the first drain material protrusion is larger than a vertical thickness of the first material body proximal to each of the first source and drain material protrusions.

In sixteenth examples, for any of the thirteenth through fifteenth examples each of the first and second source and drain material protrusions comprises a plurality of material layers. A first of the material layers proximal to the opposite ends of the first or second material bodies has a first concentration of germanium, and a second of the material layers proximal to the first or second metallization structures has a second germanium concentration, higher than the first germanium concentration.

In seventeenth examples, for any of the sixteenth examples the second of the material layers comprises a higher concentration of Ga than the first of the material layers.

In eighteenth examples a method comprises receiving a workpiece comprising a stack of channel material structure, forming a stack of individual source material bodies and a vertical stack of individual drain material bodies at opposite ends of each of the channel material structures, forming a first metallization structure in contact with each of the source material bodies, forming a second metallization structure in contact with each of drain material bodies, and forming a gate structure comprising a gate insulator material and a gate electrode material between individual ones of the channel material structures.

In nineteenth examples, for any of the eighteenth examples, forming the vertical stacks of individual source and drain material bodies comprises forming protrusions comprising silicon and a first concentration of germanium at the opposite ends of each of the channel material structures, and augmenting the protrusions by forming a material layer comprising silicon and second concentration of germanium, greater than the first concentration of germanium.

In twentieth examples, for any of the nineteenth examples forming the protrusions precedes forming the gate structure and augmenting the protrusions is subsequent to forming the gate structure.

However, the above embodiments are not limited in this regard and, in various implementations, the above embodiments may include the undertaking of only a subset of such features, undertaking a different order of such features, undertaking a different combination of such features, and/or undertaking additional features than those features explicitly listed. The scope of the invention should, therefore, be determined with reference to the appended claims.

What is claimed is:

1. An apparatus, comprising:
a vertical stack of channel material structures;
a gate structure comprising a gate insulator material and a gate electrode material between individual ones of the channel material structures;
a plurality of source or drain material bodies of a same conductivity type, wherein:
a first of of the source or drain material bodies has a first thickness and is in contact with a first of the channel material structures having a second thickness at an end proximal to the first of the source or drain material bodies; and
the first thickness is larger than the second thickness; and
a metallization structure in contact with the plurality of source or drain material bodies.

2. The apparatus of claim 1, wherein the first thickness is at least 30% larger than the second thickness.

3. The apparatus of claim 2, wherein a second of the source or drain material bodies is vertically spaced apart from the first of the channel material structures by a portion of the metallization structure.

4. The apparatus of claim 1, wherein:
a first of the source or drain material bodies comprises silicon and germanium; and
a first concentration of germanium proximal to the metallization structure is higher than a second concentration of germanium proximal to a first of the channel material structures.

5. The apparatus of claim 4, wherein:
the first concentration of germanium is over 50 at. %; and
the second concentration of germanium is less than 50 at. %.

6. The apparatus of claim 5, wherein:
the first concentration of germanium is over 60 at. %; and
the second concentration of germanium is less than 40 at. %.

7. The apparatus of claim 6, wherein:
the first concentration of germanium is less than 80 at. %; and
the second concentration of germanium is at least 20 at. %.

8. The apparatus of claim 4, wherein the plurality of source or drain material bodies comprise a first concentration of a p-type impurity proximal to the metallization structure that is higher than a second concentration of the p-type impurity proximal to the channel material structure.

9. The apparatus of claim 8, wherein:
the p-type impurity is boron and wherein the first concentration is at least 2e21 atoms/cm³; and
the second concentration is less than 2e21 atoms/cm³.

10. The apparatus of claim 1, wherein an individual one of the source or drain material bodies comprises silicon and germanium and further comprises a concentration of gallium proximal to an interface with the metallization structure.

11. The apparatus of claim 10, wherein:
the concentration of gallium is at least 1e19 atoms/cm³ within 1-3 nm of the interface with the metallization structure; and
a concentration of gallium beyond 4 nm of the interface with the metallization structure is no more than 1e18 atoms/cm³.

12. The apparatus of claim 1, wherein:
the metallization structure comprises a layer of a first metal continuously lining a trench sidewall adjacent to the stack of channel material structures; and
the first layer of metal is in contact with a sidewall of each of the plurality of source or drain material bodies, and spans a vertical separate between ones of the plurality of source or drain material bodies.

13. A transistor structure, comprising:
a first material body in a vertical stack with a second material body, wherein the first and second material bodies both comprise silicon;
a gate structure within a space between the first and second material bodies, wherein the gate structure comprises a gate electrode material and a gate insulator between the gate electrode material and each of the first and second material bodies;
a first source material protrusion and a first drain material protrusion at opposite ends of the first material body, wherein each of the first source and drain material protrusions comprise silicon and germanium;
a second source material protrusion and a second drain material protrusion at opposite ends of the second material body, wherein each of the second source and drain material protrusions comprise silicon and germanium, and wherein the second source and drain material protrusions are vertically spaced apart from the first source and drain material protrusions;
a first metallization structure in contact with both of the source material protrusions; and
a second metallization structure in contact with both of the drain material protrusions.

14. The transistor structure of claim 13, wherein:
a portion of the first metallization structure is within a vertical separation between the first and second source material protrusions; and
a portion of the second metallization structure is within a vertical separation between the first and second drain material protrusions.

15. The transistor structure of claim 13, wherein a vertical thickness of the first source material protrusion and the first drain material protrusion is larger than a vertical thickness of the first material body proximal to each of the first source and drain material protrusions.

16. The transistor structure of claim 13, wherein:
each of the first and second source and drain material protrusions comprises a plurality of material layers;
a first of the material layers proximal to the opposite ends of the first or second material bodies has a first concentration of germanium; and
a second of the material layers proximal to the first or second metallization structures has a second germanium concentration, higher than the first germanium concentration.

17. The transistor structure of claim 16, wherein the second of the material layers comprises a higher concentration of Ga than the first of the material layers.

18. A method, comprising:
receiving a workpiece comprising a stack of channel material structures;
forming a stack of individual source material bodies and a vertical stack of individual drain material bodies at opposite ends of each of the channel material structures;
forming a first metallization structure in contact with each of the source material bodies;
forming a second metallization structure in contact with each of drain material bodies; and
forming a gate structure comprising a gate insulator material and a gate electrode material between individual ones of the channel material structures.

19. The method of claim 18, wherein forming the vertical stacks of individual source and drain material bodies comprises:
forming protrusions comprising silicon and a first concentration of germanium at the opposite ends of each of the channel material structures; and
augmenting the protrusions by forming a material layer comprising silicon and second concentration of germanium, greater than the first concentration of germanium.

20. The method of claim 19, wherein forming the protrusions precedes forming the gate structure and augmenting the protrusions is subsequent to forming the gate structure.
